(19) United States
(12) Patent Application Publication
(10) Pub. No.: US 2021/0323290 A1
(43) Pub. Date: Oct. 21, 2021

(54) THERMOFORMABLE COMPOSITE FILM WITH METALLIC APPEARANCE

(71) Applicant: KLÖCKNER PENTAPLAST GMBH, Heiligenroth (DE)

(72) Inventors: Guillermo SESSA, Ciudad de Buenos Aires (AR); Claudio FONSECA, Cordoba (AR)

(73) Assignee: KLÖCKNER PENTAPLAST GMBH, Heiligenroth (DE)

(21) Appl. No.: 17/285,165

(22) PCT Filed: Oct. 11, 2019
(86) PCT No.: PCT/EP2019/077643

§ 371 Date: Apr. 14, 2021

(30) Foreign Application Priority Data
Oct. 15, 2018 (DE) 10 2018 125 540.3

(51) Int. Cl. B32B 27/08; C08J 5/18; C08J 7/04; B32B 27/32; B32B 27/30

(52) U.S. Cl. CPC B32B 27/08; C08J 5/18; C08J 7/0427; B32B 27/32; B32B 27/304; B32B 2307/406; B32B 2255/10; B32B 2255/205; B32B 2307/402; B32B 2439/70; B32B 2439/80; B32B 2250/24

(57) ABSTRACT

A double-layered or multilayered thermoformable composite film having a metallic appearance that includes a first film with a metallized surface and a gloss value in the range of 50 to 600. The inventive thermoformable composite films have an appearance that is the same as that of a composite film including a metallic foil, particularly an aluminum foil.

The present invention relates to a two- or multiple-ply thermoformable composite film with metallic appearance.

The prior art reveals a very wide variety of types of plastics films for the packaging of consumer items, foods and pharmaceutical products.

WO 2017/066779 A1 describes a multiple-ply metallic film with one or more metallized layers, primers, coatings and sealant plies. The metallic film can have an exterior coating comprising metal pigments, and can have a matt to glossy appearance.

GB 2 150 881 A discloses a decorative packaging film with a base layer made of a synthetic polymer and comprising a highly light-absorbent pigment, and with one or more surface layers made of a second synthetic transparent polymer; these comprise a quantity of 1 to 40% by weight of solid particles made of a material such as calcium carbonate with particle size 0.1 to 10 μm. The packaging film is stretched, whereupon vacuoles are formed around the solid particles in the surface layers. The appearance of the film varies from an intense opalescence to a lustrous metallic appearance.

U.S. Pat. No. 5,496,630 A relates to a multilayer thermoplastic extrudate with polished metal look. The metal look results from aluminium powder with particle size ≤50 μm in combination with nacreous pigment. The multilayer extrudate comprises a decorative layer and an opaque or transparent base layer. The decorative layer comprises in particular 100 parts by weight of polyvinyl chloride as thermoplastic matrix, 0.05 to about 4 parts by weight of aluminium powder and 0.1 to 5 parts by weight of a titanium-dioxide-coated mica pigment, and also optionally organic or inorganic colouring pigments.

It is an object of the present invention to provide a thermoformable composite film with appearance the same as that of a composite film comprising a metallic foil. In particular, the intention is to provide a composite film which has the same appearance as a composite film comprising an aluminium foil.

This object is achieved via a two- or multiple-ply thermoformable composite film comprising
a first metallic-appearance surface with CIE colour coordinates L₁*, a₁*, b₁*, where 90≤L₁*≤97, −3≤a₁*≤3, −3≤b₁*≤3;
a first film made of a first polymeric material with a metallic coating;
a second film made of a second polymeric material with CIE colour coordinates L₂*, a₂*, b₂*, where 60≤L₂*≤90, −3≤a₂*≤3, −3≤b₂*≤3;

where
the first film is arranged between the second film and the first surface, and the metallic coating of the first film is visible from the side of the first surface; and
the first surface has gloss value G₁, where 50≤G₁≤600.

Advantageous embodiments of the film of the invention are characterized in that
50≤G₁≤150, 100≤G₁≤200, 150≤G₁≤250, 200≤G₁≤300, 250≤G₁≤350, 300≤G₁≤400, 350≤G₁≤450, 400≤G₁≤500, 450≤G₁≤550 or 500≤G₁≤600;
50≤G₁≤70, 60≤G₁≤80, 70≤G₁≤90, 80≤G₁≤100, 90≤G₁≤110, 100≤G₁≤120, 110≤G₁≤130, 120≤G₁≤140, 130≤G₁≤150, 140≤G₁≤160, 150≤G₁≤170, 160≤G₁≤180, 170≤G₁≤190, 180≤G₁≤200, 190≤G₁≤210, 200≤G₁≤220, 210≤G₁≤230, 220≤G₁≤240, 230≤G₁≤250, 240≤G₁≤260, 250≤G₁≤270, 260≤G₁≤280, 270≤G₁≤290, 280≤G₁≤300, 290≤G₁≤310, 300≤G₁≤320, 310≤G₁≤330, 320≤G₁≤340, 330≤G₁≤350, 340≤G₁≤360, 350≤G₁≤370, 360≤G₁≤380, 370≤G₁≤390, 380≤G₁≤400, 390≤G₁≤410, 400≤G₁≤420, 410≤G₁≤430, 420≤G₁≤440, 430≤G₁≤450, 440≤G₁≤460, 450≤G₁≤470, 460≤G₁≤480, 470≤G₁≤490, 480≤G₁≤500, 490≤G₁≤510, 500≤G₁≤520, 510≤G₁≤530, 520≤G₁≤540, 530≤G₁≤550, 540≤G₁≤560, 550≤G₁≤570, 560≤G₁≤580, 570≤G₁≤590 or 580≤G₁≤600;
the first film has gloss value equal to G₁;
90≤L₁*≤92, 91≤L₁*≤93, 92≤L₁*≤94, 93≤L₁*≤95 or 94≤L₁*≤96 or 95≤L₁*≤97;
−3≤a₁*≤−1, −2≤a₁*≤0, −1≤a₁*≤1, 0≤a₁*≤2 or 1≤a₁*≤3;
−3.0≤a₁≤−2.6, −2.8≤a₁≤−2.4, −2.6≤a₁≤−2.2, −2.4≤a₁≤−2.0, −2.2≤−a₁≤−1.8, ≤−2.0≤−a₁≤−1.6, −1.8≤−a₁≤−1.4, ≤−1.6≤−a₁≤−1.2, −1.4≤a₁≤−1.0, −1.2≤a₁≤−0.8, −1.0≤−a₁≤−0.6, −0.8≤−a₁≤−0.4, −0.6≤a₁≤−0.2, −0.4≤a₁≤0.0, −0.2≤a₁≤0.2, 0.0≤a₁≤0.4, 0.2≤a₁≤0.6, ≤0.4≤a₁≤0.8, 0.6≤a₁≤1.0, ≤0.8≤a₁≤1.2, 1.0≤a₁≤1.4, ≤1.2≤a₁≤1.6, 1.4≤a₁≤1.8, ≤1.6≤a₁≤2.0, 1.8≤a₁≤2.2, 2.0≤a₁≤2.4, 2.2≤a₁≤2.6, 2.4≤a₁≤2.8 or 2.6≤a₁≤3.0;
−3≤b₁≤−1, −2≤b₁≤0, −1≤b₁≤1, 0≤b₁≤2 or 1≤b₁≤3;
−3.0≤b₁≤−2.6, −2.8≤b₁≤−2.4, −2.6≤b₁≤−2.2, −2.4≤b₁≤−2.0, −2.2≤b₁≤−1.8, −2.0≤b₁≤−1.6, −1.8≤b₁≤−1.4, −1.6≤b₁≤−1.2, −1.4≤b₁≤−1.0, −1.2≤b₁≤−0.8, −1.0≤b₁≤−0.6, −0.8≤b₁≤−0.4, −0.6≤b₁≤−0.2, −0.4≤b₁≤0.0, −0.2≤b₁≤0.2, 0.0≤b₁≤0.4, 0.2≤b₁≤0.6, 0.4≤b₁≤0.8, 0.6≤b₁≤1.0, 0.8≤b₁≤1.2, 1.0≤b₁≤1.4, 1.2≤b₁≤1.6, 1.4≤b₁≤1.8, 1.6≤b₁≤2.0, 1.8≤b₁≤2.2, 2.0≤b₁≤2.4, 2.2≤b₁≤2.6, 2.4≤b₁≤2.8 or 2.6≤b₁≤3.0;
the first surface of the composite film has CIE lightness including specular component L₁* and CIE lightness excluding specular component \tilde{L}₁, where 0.65·L₁*≤\tilde{L}₁≤0.9·L₁*;
the first surface of the composite film has CIE lightness excluding specular component \tilde{L}₁, where 0.65·L₁*≤\tilde{L}₁≤0.75·L₁*, 0.7·L₁*≤\tilde{L}₁≤0.8·L₁*, 0.75·L₁*≤\tilde{L}₁≤0.85·L₁* or −0.8·L₁*≤\tilde{L}₁≤0.9·L₁*;
the first surface of the composite film has CIE lightness excluding specular component \tilde{L}₁, where 0.65·L₁*≤\tilde{L}₁≤0.69·L₁*, 0.67·L₁*≤\tilde{L}₁≤0.71·L₁*, 0.70·L₁*≤\tilde{L}₁≤0.74·L₁*, 0.72·L₁*≤\tilde{L}₁≤0.76·L₁*, 0.74·L₁*≤\tilde{L}₁≤0.78·L₁*, 0.76·L₁*≤\tilde{L}₁≤0.80·L₁*, 0.78·L₁*≤\tilde{L}₁≤0.82·L₁*, 0.80·L₁*≤\tilde{L}₁≤0.84·L₁*, 0.82·L₁*≤\tilde{L}₁≤0.86·L₁*, 0.84·L₁*≤\tilde{L}₁≤0.88·L₁* or 0.86·L₁*≤\tilde{L}₁≤0.90·L₁*;
the first film has CIE colour coordinates equal to L₁*, a₁*, b₁*;
the first film has CIE lightness including specular component equal to L₁* and CIE lightness excluding specular component equal to \tilde{L}₁, where 0.65·L₁*≤\tilde{L}₁≤0.9·L₁*;
the first film has CIE lightness including specular component equal to L₁* and CIE lightness excluding specular component equal to \tilde{L}₁, where 0.65·L₁*≤\tilde{L}₁≤0.75·L₁*, 0.7·L₁*≤\tilde{L}₁≤0.8·L₁*, 0.75·L₁*≤\tilde{L}₁≤0.85·L₁* or 0.8·L₁≤\tilde{L}₁≤0.9·L₁*;
the first film has CIE lightness including specular component equal to L₁* and CIE lightness excluding specular component equal to \tilde{L}₁, where 0.65·L₁*≤\tilde{L}₁≤0.69·L₁*, 0.67·L₁*≤\tilde{L}₁≤0.71·L₁*, 0.70·L₁*≤\tilde{L}₁≤0.74·L₁*, 0.72·L₁*≤\tilde{L}₁≤0.76·L₁*, 0.74·L₁*≤\tilde{L}₁≤0.78·L₁*, 0.76·L₁*≤\tilde{L}₁≤0.80·L₁*, 0.78·L₁*≤\tilde{L}₁≤0.82·L₁*, 0.80·L₁*≤\tilde{L}₁≤0.84·L₁*, 0.82·L₁*≤\tilde{L}₁≤0.86·L₁*, 0.84·L₁*≤\tilde{L}₁≤0.88·L₁* or 0.86·L₁*≤\tilde{L}₁≤0.90·L₁*;
a CVD coating, PVD coating or sputter coating made of a metal or of a metal alloy has been provided to the first film;
a metallic coating with thickness 10 to 100 nm has been provided to the first film;
a metallic coating with thickness 10 to 30 nm, 20 to 40 nm, 30 to 50 nm, 40 to 60 nm, 50 to 70 nm, 60 to 80 nm, 70 to 90 nm or 80 to 100 nm has been provided to the first film;
a coating made of aluminium has been provided to the first film;
the first film has been metallized with aluminium;
the first film has light transmittance T₁, where 0%≤T₁≤5%;
the first film has light transmittance T₁, where 0%≤T₁≤3%, 1%≤T₁≤4% or 2%≤T₁≤5%;
the first film has light transmittance T₁, where 0%≤T₁≤0.8%, 0.4%≤T₁≤1.2%, 0.8%≤T₁≤1.6%, 1.2%≤T₁≤2%, 1.6%≤T₁≤2.4%, 2%≤T₁≤2.8%, 2.4%≤T₁≤2.2%, 2.8%≤T₁≤3.6%, 3.2%≤T₁≤4%, 3.6%≤T₁≤4.4%, 4%≤T₁≤4.8% or 4.4%≤T₁≤5%;
the metallic-coated surface of the first film has an arithmetic average roughness value Ra, where 50 nm≤Ra≤200 nm;
the metallic-coated surface of the first film has an arithmetic average roughness value Ra, where 50 nm≤Ra≤100 nm, 80 nm≤Ra≤130 nm, 110 nm≤Ra≤160 nm or 140 nm≤Ra≤200 nm;
the metallic-coated surface of the first film has an arithmetic average roughness value Ra, where 50 nm≤Ra≤70 nm, 60 nm≤Ra≤80 nm, 70 nm≤Ra≤90 nm, 80 nm≤Ra≤100 nm, 90 nm≤Ra≤110 nm, 100 nm≤Ra≤120 nm, 110 nm≤Ra≤130 nm, 120 nm≤Ra≤140 nm, 130 nm≤Ra≤150 nm, 140 nm≤Ra≤160 nm, 150 nm≤Ra≤170 nm, 160 nm≤Ra≤180 nm, 170 nm≤Ra≤190 nm or 180 nm≤Ra≤200 nm;
the first film comprises, based on its total volume, 0.005 to 0.03% by volume of titanium dioxide particles with average equivalent diameter 0.2 to 0.35 μm;
the first film comprises, based on its total volume, 0.005 to 0.009% by volume, 0.007 to 0.011% by volume, 0.009 to 0.013% by volume, 0.011 to 0.015% by volume, 0.013 to 0.017% by volume, 0.015 to 0.019% by volume, 0.017 to 0.021% by volume, 0.019 to 0.023% by volume, 0.021 to 0.025% by volume, 0.023 to 0.027% by volume or 0.025 to 0.03% by volume of titanium dioxide particles with average equivalent diameter 0.2 to 0.35 μm;
the first film comprises, based on its total volume, 0.02 to 2% by volume of bubbles with average diameter 0.1 to 2 μm;
the first film consists of a polymeric backing film and a metallic coating;
the polymeric backing film of the first film has light transmittance \tilde{T}₁, where 80%≤\tilde{T}₁≤94%;
80%≤\tilde{T}₁≤86%, 84%≤\tilde{T}₁≤90% or 88%≤\tilde{T}₁≤94%;
80%≤\tilde{T}₁≤84%, 82%≤\tilde{T}₁≤86%, 84%≤\tilde{T}₁≤88%, 86%≤\tilde{T}₁≤90%, 88%≤\tilde{T}₁≤92% or 90%≤\tilde{T}₁≤94%;
the polymeric backing film of the first film has haze \tilde{H}₁, where 1%≤\tilde{H}₁≤30%;
1%≤\tilde{H}₁≤20% or 15%≤\tilde{H}₁≤30%;
1%≤\tilde{H}₁≤4%, 5%≤\tilde{H}₁≤9%, 7%≤\tilde{H}₁≤11%, 9%≤\tilde{H}₁≤13%, 11%≤\tilde{H}₁≤15%, 13%≤\tilde{H}₁≤17%, 15%≤\tilde{H}₁≤19%, 17%≤\tilde{H}₁≤21%, 19%≤\tilde{H}₁≤23%, 21%≤\tilde{H}₁≤25%, 19%≤\tilde{H}₁≤23%, 21%≤\tilde{H}₁≤25%, 23%≤\tilde{H}₁≤27% or 25%≤\tilde{H}₁≤30%;
the composite film comprises a third film which is arranged between the first film and the first surface and which has light transmittance equal to \tilde{T}₁ and haze equal to \tilde{H}₁;
the metallic-coated surface of the first film faces towards the first surface of the composite film;
the metallic-coated surface of the first film faces away from the first surface of the composite film;
the metallic-coated surface of the first film faces towards a second surface of the composite film, the first and second surface of the composite film being arranged opposite to one another;
the second polymeric material comprises, based on its total weight, 1 to 8% by weight of titanium dioxide particles and 0.001 to 0.1% by weight of carbon black particles;
the second polymeric material comprises nacreous pigment;
the second polymeric material comprises pigment particles consisting of titanium-dioxide-coated mica;
the second polymeric material comprises pigment particles consisting of mica with a titanium dioxide coating of
thickness 50 to 70 nm;
60≤L₂*≤70, 65≤L₂*≤75, 70≤L₂*≤80, 75≤L₂*≤85 or 80≤L₂*≤90;
60≤L₂*≤64, 62≤L₂*≤66, 64≤L₂*≤68, 66≤L₂*≤70, 68≤L₂*≤72, 70≤L₂*≤74, 72≤L₂*≤76, 74≤L₂*≤78, 76≤L₂*≤80, 78≤L₂*≤82, 80≤L₂*≤84, 82≤L₂*≤86, 84≤L₂*≤88 or 86≤L₂*≤90;
−3.0≤a₂*≤−2.6, −2.8≤a₂*≤−2.4, −2.6≤a₂*≤−2.2, −2.4≤a₂*≤−2.0, −2.2≤a₂*≤−1.8, −2.0≤a₂*≤−1.6, −1.8≤a₂*≤−1.4, −1.6≤a₂*≤−1.2, −1.4≤a₂*≤−1.0, −1.2≤a₂*≤−0.8, −1.0≤a₂*≤−0.6, −0.8≤a₂*≤−0.4, −0.6≤a₂*≤−0.2, −0.4≤a₂*≤0.0, −0.2≤a₂*≤0.2, −0.0≤a₂*≤0.4, 0.2≤a₂*≤0.6, 0.4≤a₂*≤0.8, 0.6≤a₂*≤1.0, 0.8≤a₂*≤1.2, 1.0≤a₂*≤1.4, 1.2≤a₂*≤1.6, 1.4≤a₂*≤1.8, 1.6≤a₂*≤2.0, 1.8≤a₂*≤2.2, 2.0≤a₂*≤2.4, 2.2≤a₂*≤2.6, 2.4≤a₂*≤2.8 or 2.6≤a₂*≤3.0;
−3≤b₂*≤−1, −2≤b₂*≤0, −1≤b₂*≤1, 0≤b₂*≤2 or 1≤b₂*≤3;
−3.0≤b₂*≤−2.6, −2.8≤b₂*≤−2.4, −2.6≤b₂*≤−2.2, −2.4≤b₂*≤−2.0, −2.2≤b₂*≤−1.8, −2.0≤b₂*≤−1.6, −1.8≤b₂*≤−1.4, −1.6≤b₂*≤−1.2, −1.4≤b₂*≤−1.0, −1.2≤b₂*≤−0.8, −1.0≤b₂*≤−0.6, −0.8≤b₂*≤−0.4, −0.6≤b₂*≤−0.2, −0.4≤b₂*≤0.0, −0.2≤b₂*≤0.2, 0.0≤b₂*≤0.4, 0.2≤b₂*≤0.6, 0.4≤b₂*≤0.8, 0.6≤b₂*≤1.0, 0.8≤b₂*≤1.2, 1.0≤b₂*≤1.4, 1.2≤b₂*≤1.6, 1.4≤b₂*≤1.8, 1.6≤b₂*≤2.0, 1.8≤b₂*≤2.2, 2.0≤b₂*≤2.4, 2.2≤b₂*≤2.6, 2.4≤b₂*≤2.8 or 2.6≤b₂*≤3.0;
the second film has light transmittance T₂, where 0%≤T₂≤20%;
0%≤T₂≤4%, 2%≤T₂≤6%, 4%≤T₂≤8%, 6%≤T₂≤10%, 8%≤T₂≤12%, 10%≤T₂≤14%, 12%≤T₂≤16%, 14%≤T₂≤18% or 16%≤T₂≤20%;
the composite film has a thickness from 30 to 2000 μm;
the composite film has a thickness from 30 to 600 μm, 300 to 900 μm, 600 to 1200 μm, 900 to 1500 μm, 1200 to 1800 μm or 1400 to 2000 μm;
the composite film has a thickness from 30 to 200 μm, 100 to 300 μm, 200 to 400 μm, 300 to 500 μm, 400 to 600 μm, 500 to 700 μm, 600 to 800 μm, 700 to 900 μm, 800 to 1000 μm, 900 to 1100 μm, 1000 to 1200 μm, 1100 to 1300 μm, 1200 to 1400 μm, 1300 to 1500 μm, 1400 to 1600 μm, 1500 to 1700 μm, 1600 to 1800 μm, 1700 to 1900 μm or 1800 to 2000 μm;
the composite film has a thickness from 30 to 70 μm, 50 to 90 μm, 70 to 110 μm, 90 to 130 μm, 110 to 150 μm, 130 to 170 μm, 150 to 190 μm, 170 to 210 μm, 190 to 230 μm, 210 to 250 μm, 230 to 270 μm, 250 to 290 μm, 270 to 310 μm, 290 to 330 μm, 310 to 350 μm, 330 to 370 μm, 350 to 390 μm, 370 to 410 μm, 390 to 430 μm, 410 to 450 μm, 430 to 470 μm, 450 to 490 μm or 470 to 510 μm;
the composite film has a length from 1 to 10000 m;
the composite film has a length from 1 to 60 m, 30 to 90 m, 60 to 120 m, 90 to 150 m, 120 to 180 m or 130 to 200 m;
the composite film has a length from 1 to 1000 m, 500 to 1500 m, 1000 to 2000 m, 1500 to 2500 m, 2000 to 3000 m, 2500 to 3500 m, 3000 to 4000 m, 3500 to 4500 m, 4000 to 5000 m, 4500 to 5500 m, 5000 to 6000 m, 5500 to 6500 m, 6000 to 7000 m, 6500 to 7500 m, 7000 to 8000 m, 7500 to 8500 m, 8000 to 9000 m, 8500 to 9500 m or 9000 to 10000 m;
the composite film has a width from 5 cm to 8 m;
the composite film has a width from 5 cm to 2 m, 1 to 3 m, 2 to 4 m, 3 to 5 m, 4 to 6 m, 5 to 7 m or 6 to 8 m;
the composite film has a width from 5 to 20 cm, 10 to 30 cm, 20 to 40 cm, 30 to 50 cm, 40 to 60 cm, 50 to 70 cm, 60 to 80 cm, 70 to 90 cm or 80 to 100 cm;
the first film has thickness 10 to 100 μm;
the first film has thickness 10 to 60 μm or 50 to 100 μm;
the first film has thickness 10 to 20 μm, 15 to 25 μm, 20 to 30 μm, 25 to 35 μm, 30 to 40 μm, 35 to 45 μm, 40 to 50 μm, 45 to 55 μm, 50 to 60 μm, 55 to 65 μm, 60 to 70 μm, 65 to 75 μm, 70 to 80 μm, 75 to 85 μm, 80 to 90 μm, 85 to 95 μm or 90 to 100 μm;
the second film has thickness 30 to 1000 μm;
the second film has thickness 30 to 600 μm or 500 to 1000 μm;
the second film has thickness 30 to 200 μm, 100 to 300 μm, 200 to 400 μm, 300 to 500 μm, 400 to 600 μm, 500 to 700 μm, 600 to 800 μm, 500 to 700 μm, 600 to 800 μm, 700 to 900 μm or 800 to 1000 μm;
the first polymeric material consists of, based on its total weight, 60 to 99% by weight of one or more polymers selected from the group comprising vinyl chloride polymer (VCP), polypropylene (PP), polyester and cycloolefin copolymer (COC), and also 1 to 40% by weight of one or more additives;
the first polymeric material consists of, based on its total weight, 60 to 99% by weight of polypropylene (PP) and 1 to 40% by weight of one or more additives;
the second polymeric material consists of, based on its total weight, 60 to 99% by weight of one or more polymers selected from the group comprising vinyl chloride polymer (VCP), polypropylene (PP), polyester and cycloolefin copolymer (COC), and also 1 to 40% by weight of one or more additives;
the second polymeric material consists of, based on its total weight, 60 to 99% by weight of vinyl chloride polymer (VCP) and 1 to 40% by weight of one or more additives;
the second polymeric material consists of, based on its total weight, 60 to 99% by weight of polyvinyl chloride (PVC) and 1 to 40% by weight of one or more additives;
the third film has thickness 10 to 100 μm;
the third film has thickness 10 to 60 μm or 50 to 100 μm;
the third film has thickness 10 to 20 μm, 15 to 25 μm, 20 to 30 μm, 25 to 35 μm, 30 to 40 μm, 35 to 45 μm, 40 to 50 μm, 45 to 55 μm, 50 to 60 μm, 55 to 65 μm, 60 to 70 μm, 65 to 75 μm, 70 to 80 μm, 75 to 85 μm, 80 to 90 μm, 85 to 95 μm or 90 to 100 μm;
the third film has been manufactured from a polymeric material which consists of, based on its total weight, 60 to 99% by weight of one or more polymers selected from the group comprising vinyl chloride polymer (VCP), polypropylene (PP), polyester and cycloolefin copolymer (COC), and also 1 to 40% by weight of one or more additives;
the third film comprises, based on its total volume, 0.005 to 0.03% by volume of titanium dioxide particles with average equivalent diameter 0.2 to 0.35 μm;
the third film comprises, based on its total volume, 0.005 to 0.009% by volume, 0.007 to 0.011% by volume, 0.009 to 0.013% by volume, 0.011 to 0.015% by volume, 0.013 to 0.017% by volume, 0.015 to 0.019% by volume, 0.017 to 0.021% by volume, 0.019 to 0.023% by volume, 0.021 to 0.025% by volume, 0.023 to 0.027% by volume or 0.025 to 0.03% by volume of titanium dioxide particles with average equivalent diameter 0.2 to 0.35 μm;
the third film comprises, based on its total volume, 0.02 to 2% by volume of bubbles with average diameter 0.1 to 2 μm;
the composite film comprises one or more plies, each of thickness 10 to 120 μm, made of a third polymeric material which consists of, based on its total weight, 60 to 99% by weight of polyvinylidene chloride (PVdC) and 1 to 40% by weight of one or more additives;
the composite film comprises one or more mutually adjacent plies made of a third polymeric material which consists of, based on its total weight, 60 to 99% by weight of polyvinylidene chloride (PVdC) and 1 to 40% by weight of one or more additives, and the total weight per unit area of the one or more mutually adjacent plies is 10 to 360 g·m⁻²;
the composite film comprises one or more mutually adjacent plies made of a third polymeric material which consists of, based on its total weight, 60 to 99% by weight of polyvinylidene chloride (PVdC) and 1 to 40% by weight of one or more additives, and the total weight per unit area of the one or more mutually adjacent plies is 10 to 50 g·m⁻², 40 to 80 g·m⁻², 60 to 100 g·m⁻², 80 to 120 g·m⁻², 100 to 140 g·m⁻², 120 to −160 g·m⁻², 140 to −180 g·m⁻², 160 to 200 g·m⁻², 180 to −220 g·m⁻², 200 to −240 g·m⁻², 220 to 260 g·m⁻², 240 to −280 g·m⁻², 260 to −300 g·m⁻², 280 to 320 g·m⁻², 300 to 340 g·m⁻² or 320 to 360 g·m⁻²;
the light transmittance of the one or more plies made of the third polymeric material is 75% to 94%;
the composite film comprises one or more plies, each of thickness 15 to 160 μm, made of a fourth polymeric material which consists of, based on its total weight, 60 to 99% by weight of polychlorotrifluoroethylene (PCTFE) and 1 to 40% by weight of one or more additives;
the light transmittance of the one or more plies made of the fourth polymeric material is 75% to 94%;
the composite film comprises one or more plies, each of thickness 1 to 50 μm, made of a fifth polymeric material which consists of, based on its total weight, 60 to 99% by weight of ethylene-vinyl alcohol copolymer (EVOH) and 1 to 40% by weight of one or more additives;
the light transmittance of the one or more plies made of the fifth polymeric material is 75% to 94%;
the composite film comprises one or more plies, each of thickness 15 to 400 μm, made of a sixth polymeric material which consists of, based on its total weight, 60 to 99% by weight of cycloolefin copolymer (COC) and 1 to 40% by weight of one or more additives;
the light transmittance of the one or more plies made of the sixth polymeric material is 70% to 94%;
the composite film comprises one or more plies, each of thickness 20 to 600 μm, made of a seventh polymeric material which consists of, based on its total weight, 60 to 99% by weight of vinyl chloride polymer (VCP) and 1 to 40% by weight of one or more additives;
the light transmittance of the one or more plies made of the seventh polymeric material is 75% to 94%;
the composite film comprises one or more plies, each of thickness 20 to 600 μm, made of an eighth polymeric material which consists of, based on its total weight, 60 to 99% by weight of polyvinyl chloride (PVC) and 1 to 40% by weight of one or more additives;
the light transmittance of the one or more plies made of the eighth polymeric material is 75% to 94%;
the composite film comprises one or more plies, each of thickness 20 to 1200 μm, made of a ninth polymeric material which consists of, based on its total weight, 60 to 99% by weight of polyester and 1 to 40% by weight of one or more additives;
the light transmittance of the one or more plies made of the ninth polymeric material is 75% to 94%;
the composite film comprises one or more plies, each of thickness 15 to 60 μm, made of a tenth polymeric material which consists of, based on its total weight, 60 to 99% by weight of polyethylene (PE) and 1 to 40% by weight of one or more additives;
the light transmittance of the one or more plies made of the tenth polymeric material is 75% to 94%;
the composite film comprises one or more plies, each of thickness 15 to 400 μm, made of an eleventh polymeric material which consists of, based on its total weight, 60 to 99% by weight of cycloolefin polymer (COP) and 1 to 40% by weight of one or more additives;
the light transmittance of the one or more plies made of the eleventh polymeric material is 70% to 94%;
the composite film comprises a coextruded film with five layers with the sequence PE/tie layer/EVOH/tie layer/PE in each case made of a polymeric material with a proportion by weight of 60 to 99% by weight of polyethylene (PE), 60 to 99% by weight of ethylene-vinyl alcohol copolymer (EVOH) and 60 to 99% by weight of polyethylene (PE), based on the total weight of the respective layer;
the composite film comprises, in addition to the first and second film, one, two, three, four, five, six, seven, eight or nine further films made of polymeric materials;
the composite film comprises, in addition to the first and second film, one, two, three, four, five, six, seven, eight or nine layers made of polymeric materials;
the composite film comprises, in addition to the first and second film, one, two, three, four, five, six, seven, eight or nine films and/or layers made of polymeric materials;
the composite film comprises, in addition to the first and second film, one, two, three, four, five, six, seven, eight or nine plies made of polymeric materials;
the composite film comprises, in addition to the first and second film, one, two, three, four, five, six, seven, eight or nine films and/or plies made of polymeric materials;
the composite film comprises a tie layer; and/or
the composite film comprises two, three, four, five, six, seven, eight or nine tie layers.

The invention further provides items such as trays, pots and blister packs produced by thermoforming from one of the films described above.

The first and second film of the composite film of the invention are of decisive importance for the appearance of packaging thermoformed therefrom, an example being a blister pack for pharmaceutical products or food supplements in the form of tablets and of pills.

In thermoforming, a single- or multiple-ply polymeric film is heated to a temperature in the range 90 to 150° C. and pressed or drawn pneumatically or by means of vacuum into a mould made of a metallic material. Certain regions of the film are stretched here by a factor of up to 6. If the film comprises a metallic coating, this becomes damaged in the stretched regions. A streaked pattern often arises here, made of alternating metallic-coated and uncoated polymer. In the regions that have been stretched or “damaged” in this way, the metallic coating is partially transparent.

The first, metallic-coated film of the composite film of the invention faces towards a visible side of packaging thermoformed therefrom. The second film of the composite film of the invention is arranged within the thermoformed packaging on an internal side that is obscured by the first film.

Accordingly, the first film is primarily responsible for the metallic appearance of the composite film of the invention. The second film serves to reduce the adverse visual effect of cracks and other defects produced in the metallic coating of the first film during thermoforming.

Surprisingly, the inventors have found that by modifying the first film or the polymeric backing film used for the metallic coating of the first film, it is possible to replicate almost precisely the appearance of a metal foil, for example an aluminium foil.

During the course of exhaustive experiments, the inventors have found various methods for achieving the desired metallic appearance. These methods comprise nano- or submicro-scale texturing of the surface provided for the metallic coating within the first film, and also the use of particulate additives or bubbles to provide optical haze. The first film, or the polymeric backing film used for the metallic coating within the first film, is produced with the aid of a conventional extrusion system with flat-film die, chill roll and two or more take-off rolls.

A nano- or submicro-scale texture is produced in the surface provided for the metallic coating within the polymeric backing film of the first film by using a ceramically coated, chemically etched, sandblasted or electro-eroded chill roll during extrusion.

The nano- or submicro-scale surface texture of the first film increases the proportion of diffuse reflection from the metallic coating. The resultant optical mattness can be perceived on both sides of the metallic coating. Accordingly, the arrangement of the first film in this embodiment can, if desired, be such that the metallic coating of the first film faces towards or away from the first surface of the external side, or the observer.

In an alternative to the above, the polymeric backing film of the first film exhibits optical haze. To this end, the polymeric backing film of the first film is produced from a polymeric material with a particulate or bubble-forming additive. Titanium dioxide is particularly suitable as particulate additive because of its high refractive index: 2.7. In another embodiment that is likewise advantageous, micro-scale glass beads or micro-scale polymer beads are used.

In another extrusion process for producing haze in a polymeric backing film of the first film, a chill roll temperature-controlled to 50 to 80° C. is used to promote growth of crystalline spherulites.

When a first film with optical haze is used, the first film is arranged in the composite film of the invention in a manner such that the polymeric backing film exhibiting optical haze faces towards the first surface or outwards towards the observer, and such that the metallic coating faces away from the first surface or the observer.

A three-ply composite film was produced according to the invention by means of lamination with the following structure or ply sequence:
second film/tie layer/first film/tie layer/PCTFE

where
PCTFE is PCTFE film of thickness 51 μm,
first film is polypropylene film (cast PP) of thickness 25 μm metallized with aluminium of thickness 40 nm,
second film is PVC film of thickness 200 μm comprising 0.06% by weight of carbon black and 2.5% by weight of titanium dioxide,

where the PCTFE film forms the first surface of the composite film, and the aluminium-metallized side of the first film faces towards the second film.

Table 1 below shows the evaluation, by a test panel of twelve people, of the above composite film of the invention and of a comparative conventional metallized film.

TABLE 1
Visual evaluation

| Visual | | Comparative |
|---|---|---|
| category | Invention | film |
| Gloss | 3.8 | 2.6 |
| Colour | 3.8 | 3.2 |
| Volume | 3.9 | 3.3 |
| Orange skin | 4.6 | 2.0 |
| Scratches | 4.0 | 3.2 |
| Spots | 3.6 | 2.5 |
| Naturalness | 3.6 | 2.7 |
| Average | 3.9 | 2.8 |

The values shown in Table 1 indicate similarity to an aluminium foil on a qualitative scale from 1 to 5 as follows: 1≡not similar, 2≡in part similar, 3≡similar, 4≡very similar, 5≡indistinguishable.

In advantageous embodiments, the composite film comprises, alongside the first and second film, further plies or, respectively, films made of polymeric materials with specific properties, for example modulus of elasticity, optical transparency, or high barrier to water vapour or oxygen. Accordingly, the other optional plies or films consist of polymeric materials based on polyvinylidene chloride (PVdC), polychlorotrifluoroethylene (PCTFE), ethylene-vinyl alcohol copolymer (EVOH), cycloolefin copolymer (COC), cycloolefin polymer (COP), polyester, vinyl chloride polymer (VCP), polypropylene (PP) and polyethylene (PE).

Each of the optional other layers or films is mutually independently arranged in relation to the first surface of the composite film of the invention for the first film, between the first and second film or after the second film.

In an advantageous embodiment, a film made of a material based on PCTFE is arranged before the first film and forms the first surface of the composite film of the invention. In relation to the first surface of the composite film, this arrangement corresponds to the sequence PCTFE/F1/F2, where F1 is the first film and F2 is the second film.

In another advantageous embodiment, a film made of a material based on PVdC is arranged after the second film F2 and forms the second surface of the composite film of the invention. In relation to the first surface of the composite film, this arrangement corresponds to the sequence F1/F2/PVdC, where F1 forms the first surface of the composite film.

In another advantageous embodiment, a film made of a material based on PE is arranged between the first and second film. In relation to the first surface of the composite film, this arrangement corresponds to the sequence F1/PE/F2, where F1 forms the first layer of the composite film.

In other advantageous embodiments, the composite film of the invention comprises, in addition to the first film F1 and second film F2, one or more plies, layers and/or films arranged in the following sequence in relation to the first surface of the composite film: PCTFE/F1/F2, PVC/Aclar/F1/F2, PVC/PCTFE/F1/F2, PVC/EVOH-PE/Aclar/F1/F2, PVC/EVOH-PE/PCTFE/F1/F2, PVdC/F1/F2, PVdC/PE/F1/F2, PVC/PVdC/F1/F2.

The first film preferably comprises a polymeric backing film which consists of a material based on polypropylene (PP).

It is preferable that the second film consists of a material based on polyvinyl chloride (PVC).

Expressions of the type “in relation to the first surface” and “viewed from the first surface” in the present invention refer to the beginning of a sequence of films, plies or layers present in the composite film, where the first member of the sequence forms the first surface of the composite film or is closest to the first surface of the composite film.

The term “film” or “foil” in the present invention means separate pieces of a film or foil with dimensions 0.1 to 1 m, or else industrially produced film webs or foil webs with lengths of several hundred to several thousand metres.

The expression “machine direction” or “longitudinal direction” in the present invention means the direction of transport or of winding of the extruders, calenders, laminating machines or coating machines used for the production of the composite film and of the films present therein. Accordingly, the expression “transverse direction” means a direction perpendicular to the machine direction.

The expression “polymeric material” in the present invention means in each case a polymeric material which comprises one or more polymers and one or more additives and which, during plastification in an extruder or in a kneading assembly, forms a substantially homogeneous mixture or homogeneous phase, or in the case of polyvinylidene chloride, can be applied in the form of an aqueous dispersion coating to a substrate.

The term “additives” in the present invention means substances such as processing aids, heat stabilizers, lubricants, waxes, fats, paraffins, epoxidized soya oil, polymeric modifiers, acrylate-based polymers, butyl methacrylate, butyl methacrylate-styrene, methyl methacrylate-butadiene-styrene, chlorinated polyethylene, foaming agents, matting agents, inorganic fillers, fungicides, UV stabilizers, flame retardants and fragrances.

The term “polychlorotrifluoroethylene (PCTFE)” in the present invention means homopolymers made of chlorotrifluoroethylene units and copolymers which comprise chlorotrifluoroethylene units and by way of example vinylidene fluoride units.

The term “polyethylene (PE)” in the present invention means homopolymers made of ethene units of the following type: HDPE, LDPE, LLDPE, HMWPE or UHMWPE, and also mixtures of the above types.

The term “polypropylene (PP)” in the present invention means homopolymers made of propene units, copolymers made of propene units and ethene units, and also mixtures of the above homo- and copolymers.

The expression “cycloolefin copolymer (COC)” in the present invention means copolymers made of cycloolefins, for example norbornene, with alk-1-enes, for example ethene, and also mixtures with other polyalkenes, for example HDPE.

The expression “cycloolefin polymer (COP)” in the present invention means polymers made of cycloolefins, for example norbornene, with alk-1-enes, for example ethene, and also mixtures with other polyalkenes, for example HDPE.

The expression “ethylene-vinyl alcohol copolymer (EVOH)” in the present invention means copolymers made of the monomers ethene and vinyl alcohol.

The term “polyvinylidene chloride (PVdC)” in the present invention means homopolymers made of vinylidene chloride and copolymers made of vinylidene chloride and one or more comonomers. It is preferable to use PVdC copolymers which consist of vinylidene chloride and one or more comonomers selected from the group comprising vinyl chloride, acrylates, alkyl acrylates, alkyl methacrylates and acrylonitrile.

The expression “vinyl chloride polymers (VCP)” in the present invention means vinyl chloride homopolymers, vinyl chloride copolymers, and also mixtures of the above polymers. In particular, the expression comprises “vinyl chloride polymer”
polyvinyl chlorides (PVC) produced via homopolymerization of vinyl chloride,
vinyl chloride copolymers formed via copolymerization of vinyl chloride with one or more comonomers, for example ethylene, propylene or vinyl acetate; and
mixtures of the above homopolymers and copolymers.

The term “polyester” in the present invention means semicrystalline or amorphous homo- or copolyesters. A preferred material used as semicrystalline or amorphous polyester is glycol-modified polyethyleneterephthalate (PETG) or acid-modified polyethyleneterephthalate. In particular, glycol units in amorphous glycol modified polyethyleneterephthalate (PETG) have been replaced by 1,4-cyclohexanedimethanol units. This type of 1,4-cyclohexanedimethanol-modified polyethylenetere-phthalate is marketed by Eastman Chemical Company (Tennessee, USA) as Eastar Copolyester 6763.

In another advantageous embodiment of the invention, a semicrystalline or amorphous polyester with crystallization half-life time at least 5 minutes is used. This type of copolyester is described by way of example in the Patent EP 1 066 339 B1 of Eastman Chemical Company. This copolyester is composed of (i) diacid-moiety components and (ii) diol-moiety components. The diacid-moiety components (i) comprise at least 80 mol % of a diacid-moiety component selected from terephthalic acid, naphthalenedicarboxylic acid, 1,4-cyclohexanedicarboxylic acid, isophthalic acid and mixtures thereof, based on all of the diacid-moiety components (=100 mol %) present in the copolyester. The diol-moiety components (ii) comprise 80 to 100 mol % of a diol-moiety component selected from diols having 2 to 10 carbon atoms and mixtures thereof and 0 to 20 mol % of a modifying diol selected from 1,3-propanediol, 1,4-butanediol, 1,5-pentanediol, 1,6-hexanediol, 1,8-octanediol, 2,2,4-trimethyl-1,3-pentanediol, propylene glycol, 2,2,4,4-tetramethyl-1,3-cyclobutanediol, based on all of the diol moieties (=100 mol %) present in the copolyester. Amorphous or semicrystalline copolyesters with crystallization half-life time at least 5 minutes have good suitability for conventional calendering processes. With a polymeric material comprising a substantial proportion—generally more than 50% by weight—of semicrystalline or amorphous copolyester with crystallization of half-life time at least 5 minutes it is possible to produce, via calendering, films that are homogeneous and practically defect-free.

Amorphous or semicrystalline polyesters with crystallization half-life time at least 5 minutes are inter alia marketed by Eastman Chemical Company as Cadence copolyesters. These copolyesters are used as main component for the production of polyester films, where their proportion, based on the total weight of the polyester film, is generally more than 40 to 70% by weight.

The crystallization half-life time of the copolyesters used for the film is determined with the aid of a differential scanning calorimeter or DSC. DSC is a standard method for measuring the thermal properties, in particular the phase transition temperatures, of solids. Crystallization half-life time is determined in the present invention by taking 15 mg of the copolyester to be tested, heating the same to 290° C., then cooling to a prescribed temperature of 180 to 210° C. in the presence of helium at a rate of 320° C. per minute, and detecting the time required to reach the isothermal crystallization temperature or the crystallization peak of the DSC curve. Crystallization half-life time is determined from the progress of crystallization as a function of time. The crystallization half-life time is the time required at the prescribed temperature of 180 to 210° C. after the initial phase of crystallization to obtain 50% of the maximal achievable crystallinity in the sample.

In advantageous embodiments of the film of the invention, two or more plies or films are mutually independently bonded to one another by the same adhesion promoter or by different adhesion promoters. Materials preferably used as adhesion promoters are polyurethanes or acrylates which comprise hydrolysis groups, with or without crosslinking by polyisocyanates. In some production processes, e.g. coextrusion, it is possible in some cases to bond plies made of different polymers directly, i.e. without adhesion promoter.

Test Methods

Density of films is determined in accordance with DIN EN ISO 1183:2005, and thickness is determined in accordance with DIN 53370:2006.

The average roughness value Rₐ of film surfaces is determined by means of a tactile profilometer, for example with a “Hommel-Etamic W20” instrument from Jenoptik or a “Perthometer S2/PGK” instrument from Mahr. The measurement is made in accordance with the standards DIN EN ISO 4287:2010 and DIN EN ISO 16610-21:2013. The radius of the sensor tip used here is below 2 μm. The total traversed distance lᵣ is ≥8 mm for each roughness measurement. The value used as limiting wavelength λ_{c} for the low-pass filter to separate roughness and corrugation in accordance with DIN EN ISO 16610-21:2013 is λ_{c}=0.8 mm. Average roughness value is calculated from the formula

$${R}_{a} = \frac{1}{{l}_{r}} {\int }_{0}^{{l}_{r}} \vert Z ( x ) \vert dx$$

where Z(x) denotes the measured excursion perpendicularly to the film surface (depth or height) as a function of the scanning position x.

The CIE colour coordinates L*, a*, b* of films are measured in accordance with DIN 5033-7:2014-10, with the following parameters:

| | |
|---|---|
| Light source | D65 |
| Observer | 10° |
| Measurement mode | Reflection |
| Measurement geometry | di:8 , de:8 |
| Measurement field | 8 mm (MAV) |
| Specular component | Yes (specular component |
| | included, SCI) |

CIE lightness \tilde{L}₁ excluding specular component (specular component excluded, SCE) is determined analogously.

The gloss value of films is determined in accordance with DIN EN ISO 2813:2015-02 at a measurement angle of 20°.

The light transmittance of films is measured in accordance with DIN EN ISO 13468-2:2006-07 by a double-beam spectrophotometer with D65 light source.

Haze of films is determined in accordance with DIN EN ISO 13468-1:1997-01 or ASTM D1003, procedure A, by a single-beam spectrophotometer with D65 light source.

1. A two- or multiple-ply thermoformable composite film comprising
a first metallic-appearance surface with CIE color coordinates L₁*, a₁*, b₁*, where 90≤L₁*≤97, −3≤a₁*≤3, −3≤b₁*≤3;
a first film made of a first polymeric material with a metallic coating;
a second film made of a second polymeric material with CIE color coordinates L₂*, a₂*, b₂*, where 60≤L₂*≤90, −3≤a₂*≤3, −3≤b₂*≤3;
where
the first film is arranged between the second film and the first surface, and the metallic coating of the first film is visible from a side of the first surface;
wherein
the first surface has gloss value G₁, where 50≤G₁≤600.

2. The composite film according to claim 1, wherein
50≤G₁≤150, 100≤G₁≤200, 150≤G₁≤250, 200≤G₁≤300, 250≤G₁≤350, 300≤G₁≤400, 350≤G₁≤450, 400≤G₁≤500, 450≤G₁≤550 or 500≤G₁≤600.

3. The composite film according to claim 1, wherein the first surface has CIE lightness including specular component L₁* and CIE lightness excluding specular component \tilde{L}₁, where 0.65·L₁*≤\tilde{L}₁≤0.9·L₁*.

4. The composite film according to claim 1, wherein the first film has CIE colour coordinates equal to L₁*, a₁*, b₁*.

5. The composite film according to claim 1, wherein the first film has CIE lightness including specular component equal to L₁* and CIE lightness excluding specular component equal to \tilde{L}₁, where 0.65·L₁*≤\tilde{L}₁≤0.9·L₁*.

6. The composite film according to claim 1, wherein a CVD coating, PVD coating or sputter coating made of a metal or of a metal alloy has been disposed on the first film.

7. The composite film according to claim 1, wherein a coating made of aluminum has been disposed on the first film.
